(19) United States
(12) Patent Application Publication
(10) Pub. No.: US 2002/0093799 A1
(43) Pub. Date: Jul. 18, 2002

(54) Add-in card bracket and method of fastening a printed circuit board to same

(76) Inventors: William F. Federer, West Chester, PA (US); Thomas M. Costello, Havertown, PA (US)

Correspondence Address: Harold H. Fullmer, WOODCOCK WASHBURN KURTZ, MACKIEWICZ & NORRIS LLP, One Liberty Place - 46th Floor, Philadelphia, PA, 19103, US

(21) Appl. No.: 09/760,911

(22) Filed: Jan. 16, 2001

(51) Int. Cl. H05K 5/00

(52) U.S. Cl. 361/759

(57) ABSTRACT

An add-in card includes a substantially planar printed circuit (“PCB”) and a bracket. The bracket includes tabs that extend through slots in the PCB and that are twisted to clamp the PCB and bracket together. Opposing sides or corners of a web coupled to each tab contact opposing sidewalls of the corresponding slot to position and fasten the structure in an interference fit. Thus, the fasteners accurately and repeatably position the PCB relative to the bracket within tight tolerances. An embodiment of the bracket may also include an anti-rotation member that extends outwardly from the body portion to restrain an edge of the PCB from rolling relative to the bracket in response to tightening of the tabs. A method and apparatus for positioning the components and actuating the tabs is also disclosed.

### FIELD OF THE INVENTION

The present invention relates to add-in cards for computers, and, more particularly, to add-in cards having a printed circuit board and a bracket affixed together by a deformed fastener, and to a device and method for fastening a printed circuit board to a mounting bracket.

### BACKGROUND

Add-in cards or expansion cards for computers are popular devices for adding various components or capabilities to personal computers, workstations, and the like. Such cards generally comprise a printed circuit board (“PCB”), including electronic circuitry and an L-shaped mounting bracket. The major portion of the mounting bracket, which is generally referred to as a cover or body portion, often has ports therethrough for providing access for external plugs to female connectors or jacks mounted on the PCB.

Chapter 5 of the PCI Local Bus Specification (“PCI Specification”), Revision 2.2, Dec. 18, 1998, published by the PCI Special Interest Group, Hillsboro, Oreg. 97124, provides examples and information relating to add-in card mechanical specifications. As shown in the PCI Specification, a conventional L-shaped mounting bracket includes a major, planar body portion with a pair of flanges extending substantially perpendicular from the body portion. FIGS. 5-8 of the PCI Specification provides a dimension of 4.183+/−0.010 inches (106.5+/−0.25 mm) from the body portion of the bracket (substantially perpendicular to the major face of the bracket) to a notch in the PCB connector, and another dimension of 3.950+/−0.010 inches (100.33 +/−0.25 mm) from the upper longitudinal end of the bracket to a bottom edge of the PCB. FIGS. 5-9 provides the same tolerance (that is +/−0.010 inches or 0.25 mm) for dimensions between similar reference points.

Typically, a mounting bracket and PCB are affixed together by screws or rivets that are received by holes through the mounting bracket flanges and the PCB. Unfortunately, affixing the mounting brackets and PCBs together is a time consuming, and therefore expensive, operation. Moreover, because the mounting brackets and PCBs are produced in large quantities, accurately and precisely locating the holes consistently over a large number of parts is often problematic, and relatively large tolerances are typically employed. An easier technique for affixing the mounting bracket to PCBs is desired that does not require large tolerances.

### SUMMARY

An add-in card is provided that includes a substantially planar printed circuit (“PCB”) and a bracket. The PCB includes slots formed therethrough proximate an end of the PCB. The bracket includes a body and fastening members protruding through the slots.

Each one of the fastening members includes a flange extending from the body, a web extending from the flange, and a double-ended tab extending from the web opposite the flange. The tab has an underside surface that contacts the printed circuit board to at least partially fasten the printed circuit board between the tab and the flange. Each one of the tabs is deformed by twisting relative to its web, and each one of the webs is deformed by twisting relative to its flange such that opposing sides or corners of each one of the webs urges against a sidewall of the corresponding slot. The contact between the webs and the slots positions the printed circuit board relative to the bracket and fastens the PCB and bracket together in an interference fit.

In an embodiment of the bracket, the underside of at least one end of each one of the tabs forms an oblique surface that may progressively urge against the printed circuit board as the tab is deformed to clamp the printed circuit board between the oblique surface and the flange. Because the oblique surface may tend to draw the flange inward toward the PCB, the bracket may rotate relative to the PCB upon deformation of the tabs. As a result of the rotation, under certain circumstances the bracket body and PCB lose their desired mutual perpendicularity.

In another embodiment of the bracket, the underside of each of the tabs is substantially parallel to the planar surfaces of the PCB and the flange. Twisting of the flat-underside tabs tends to produce less rotation or rolling of the bracket compared with the oblique-underside tabs. Optionally, an anti-rotation member may be provided that extends outwardly from the body to contact an edge of the printed circuit board opposite the flange. The anti-rotation member restrains the edge of the PCB to prevent rotation or rolling between the printed circuit board and the bracket upon the deformation of the tabs.

According to another aspect of the present invention, an apparatus for positioning and fastening a printed circuit board and a bracket comprises a printed circuit board support, a bracket support, a printed circuit board actuator, a first bracket positioning actuator, a second bracket positioning actuator, and a pair of deformation actuators. A slot is formed in the bracket support for receiving a bracket.

The printed circuit board actuator is coupled to the printed circuit board support for urging the printed circuit board against a stop portion of the printed circuit board support. The first bracket positioning actuator is coupled to the bracket support for urging the bracket in a direction parallel to a longitudinal axis of the bracket against a longitudinal stop portion of the bracket support. The second bracket positioning actuator is coupled to the bracket support for urging the bracket in a direction substantially parallel to a transverse axis of the bracket against a transverse stop portion of the bracket support.

Each one of the deformation actuators has jaws for receiving a tab coupled to the bracket and is capable of pivoting the jaws to twist the tabs while the bracket is urged and restrained against the bracket support and while the printed circuit board is urged and restrained against a portion of the printed circuit board support. The printed circuit board support may include a pair of opposing shoulders, each of which is capable of supporting an opposing edge of the printed circuit board.

According to another aspect of the present invention, a method of fastening a mounting bracket to a printed circuit board of a computer add-in card is provided. The method comprises the steps of inserting tabs that extend from the mounting bracket into slots formed in the printed circuit board; and twisting the tabs relative to the slots to urge an underside surface of each one of the tabs against a top surface of the printed circuit board. The twisting step causes the underside of the tabs to force or clamp a bottom surface of the printed circuit board against a base surface of the mounting bracket to at least partially secure the mounting bracket and the printed circuit board together. Each tab is twisted until a web coupled to the tab contacts the slot, as described above, to form an interference fit therebetween.

The method includes rolling the mounting bracket relative to the printed circuit board so as to enable a female connector mounted on the printed circuit board to align with a corresponding port formed in the mounting bracket. Further, the mounting bracket may be positioned in a slot formed in a bracket support and the printed circuit board may be positioned on a support prior to the twisting step.

The positing step may also include urging the printed circuit board in a direction that is substantially parallel to a longitudinal axis of the bracket against the support, urging an end portion of the bracket along a longitudinal axis of the bracket until the bracket is longitudinally restrained in the bracket slot, and urging a body portion of the bracket in a direction substantially perpendicular to the longitudinal axis of the bracket until the bracket is transversely restrained in the bracket slot. Each of the urging steps preferably is performed by an actuator to automate the positioning process, although the present invention encompasses performing the steps manually. Also, a pneumatic or hydraulic pair of jaws that twist the tab relative to the slot may perform the twisting step.

### BRIEF DESCRIPTION OF THE FIGURES

FIG. 1A is a perspective view of an add-in card according to a first embodiment of an aspect of the present invention;

FIG. 1B is a perspective view of an add-in card according to a second embodiment of an aspect of the present invention;

FIG. 2 is another perspective view of the card shown in FIG. 1A;

FIG. 3 is an exploded perspective view of the add-in card shown in FIG. 1A with the fastener in an unclamped position;

FIG. 4A is a perspective view of the bracket shown in FIG. 3 according to a first embodiment of the present invention;

FIG. 4B is a perspective view of the bracket shown in FIG. 1B (with the tabs in an undeformed state) according to the second embodiment of the present invention;

FIG. 5A is side view of the bracket shown in FIG. 4A

FIG. 5B is a side view of the bracket shown in FIG. 4B;

FIG. 6A is an enlarged view of a portion indicated by circle 6A in FIG. 5A;

FIG. 6B is an enlarged view of a portion indicated by circle 6B in FIG. 5B;

FIG. 7A is a front view of the bracket shown in FIG. 4A;

FIG. 7B is a front view of the bracket shown in FIG. 4B;

FIG. 8A is an enlarged view of a portion indicated by circle 8A in FIG. 7A;

FIG. 8B is an enlarged view of a portion indicated by circle 8B in FIG. 7B;

FIG. 9A is a top view of the bracket shown in FIG. 7A;

FIG. 9B is a bottom view of the bracket shown in FIG. 7B;

FIG. 10 is an enlarged view of a portion of the add-in card shown in FIG. 1B with a portion of the bracket removed for clarity; and

FIG. 11 is an apparatus for coupling portions of the add-in card together, according to another aspect of the present invention.

### DESCRIPTION OF A PREFERRED EMBODIMENT

The PCI Specification presents a particular problem to add-in card manufacturers and designers. As described above, the PCI Specification provides the tolerance of the dimension between the major face of the bracket and a reference point on the PCB connector, and between a reference point on the top of the bracket and the bottom edge of the PCB, as +/−0.010 (ten thousandths) inch (0.25 mm), as indicated by specification dimensions SD1 and SD2, respectively, in FIG. 2. Producing conventional cards that uniformly hold the relationship between the mounting bracket and the PCB to such tolerances is difficult in a commercial production environment because of the inherent dimensional variations associated with PCB production, metal bracket production, and assembly thereof with conventional screw or rivet fasteners. According to an aspect of the present invention, an add-in card assembly is provided that may be economically and commercially produced within tight tolerances, including the specified tolerances above. The card also eliminates separate fasteners, and may be produced faster and at lower cost than conventional assemblies.

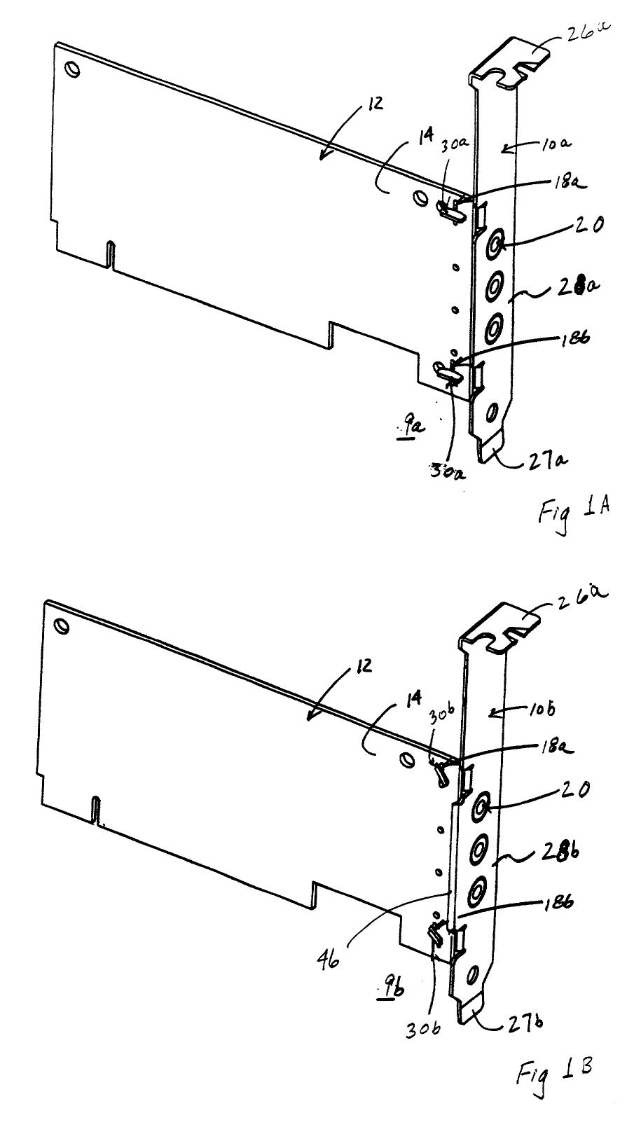

An add-in card 9a according to a first embodiment of an aspect of the present invention is shown in FIGS. 1A and 2. Add-in card 9a includes a bracket 10a and a printed circuit board (“PCB”) 12 that are mutually affixed together by a pair of fasteners 30a. PCB 12 includes conventional circuitry (not shown) and connectors (not shown) for connecting to sockets in a computer or other electronic device. According to the present invention, PCB 12 includes a first side 14, an opposing second side 16, and a pair of slots 18a and 18b disposed therethrough near an end of the PCB 12. The PCB 12 may also include output connectors, such as jacks 20, that protrude or are accessible through holes 25a formed in a body of bracket 10a.

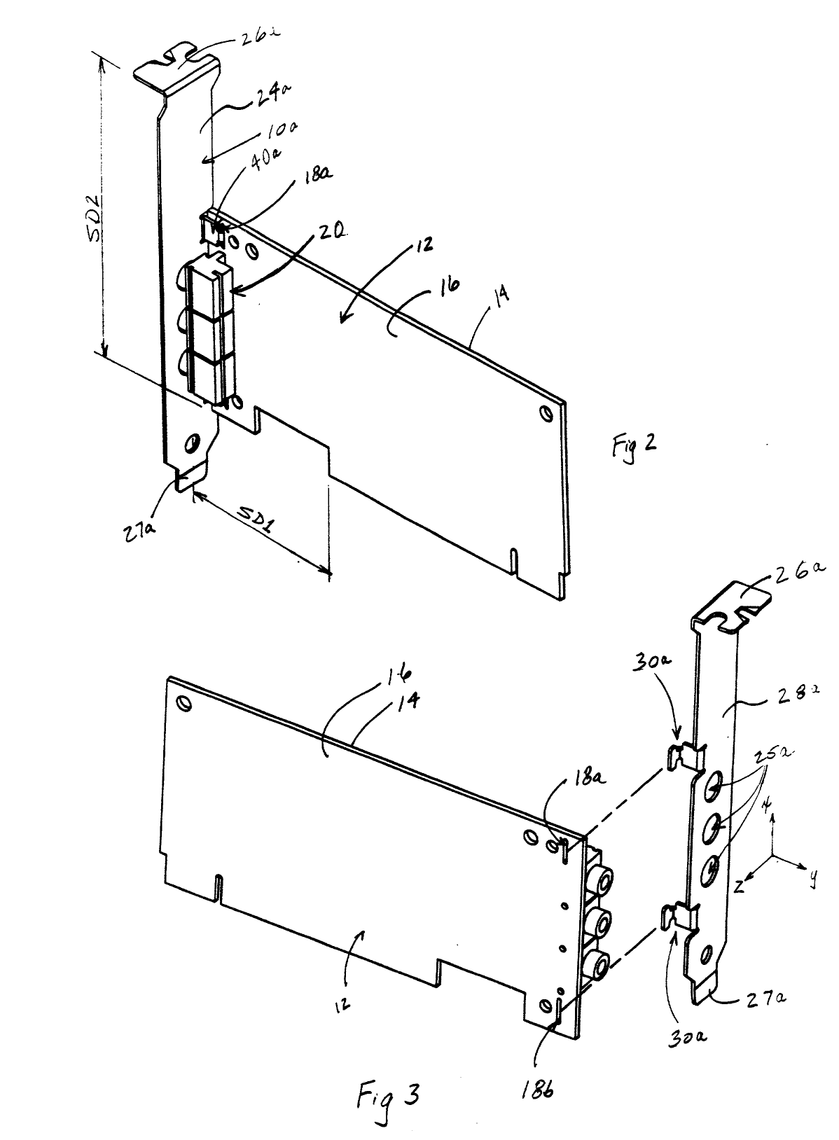

Similarly, a second embodiment of add-in card 9b is shown in FIGS. 1B and 2. Add-in card 9b includes PCB 12 as described above and a bracket 10b having a pair of fasteners 30b and holes 25b. Although FIGS. 2 and 3 are views of the first embodiment, they show the general configuration of the second embodiment except that bracket 10b is employed rather than bracket 10a.

According to the first embodiment of the present invention, bracket 10a includes a fastening end 26a, an end tab 27a opposing fastening end 26a, a substantially planar body portion 28a therebetween, and the pair of fastening members 30a. Fastening end 26a includes conventional means for attaching bracket 10a to a chassis of a computer or other electronic device, such a recessed slot for receiving a self-tapping screw. A conventional screw hole through body 28a may be formed through body portion 28a near tab 27a.

FIGS. 1A and 5A through 9A show each fastening member 30a in its unclamped state—that is, prior to bracket 10a being affixed to PCB 12. As shown for example in FIG. 6A, each fastening member 30a includes a base 32a, a web 34a, a tab 36a, and a flange 40a. As best shown in FIGS. 4A through 9A, flange 40a extends substantially perpendicularly from bracket body 28a. Web 34a extends from flange 40a and narrows therefrom (that is, flange 40a is wider than web 34a). Web 34a is bent at substantially a right angle from flange 40a such that a portion of web 34a is substantially perpendicular to flange 40a. Base 32a is formed on flange 40a and includes a portion of web 34a that is substantially parallel to flange 40a and a portion that is bent at a substantially right angle to flange 40a.

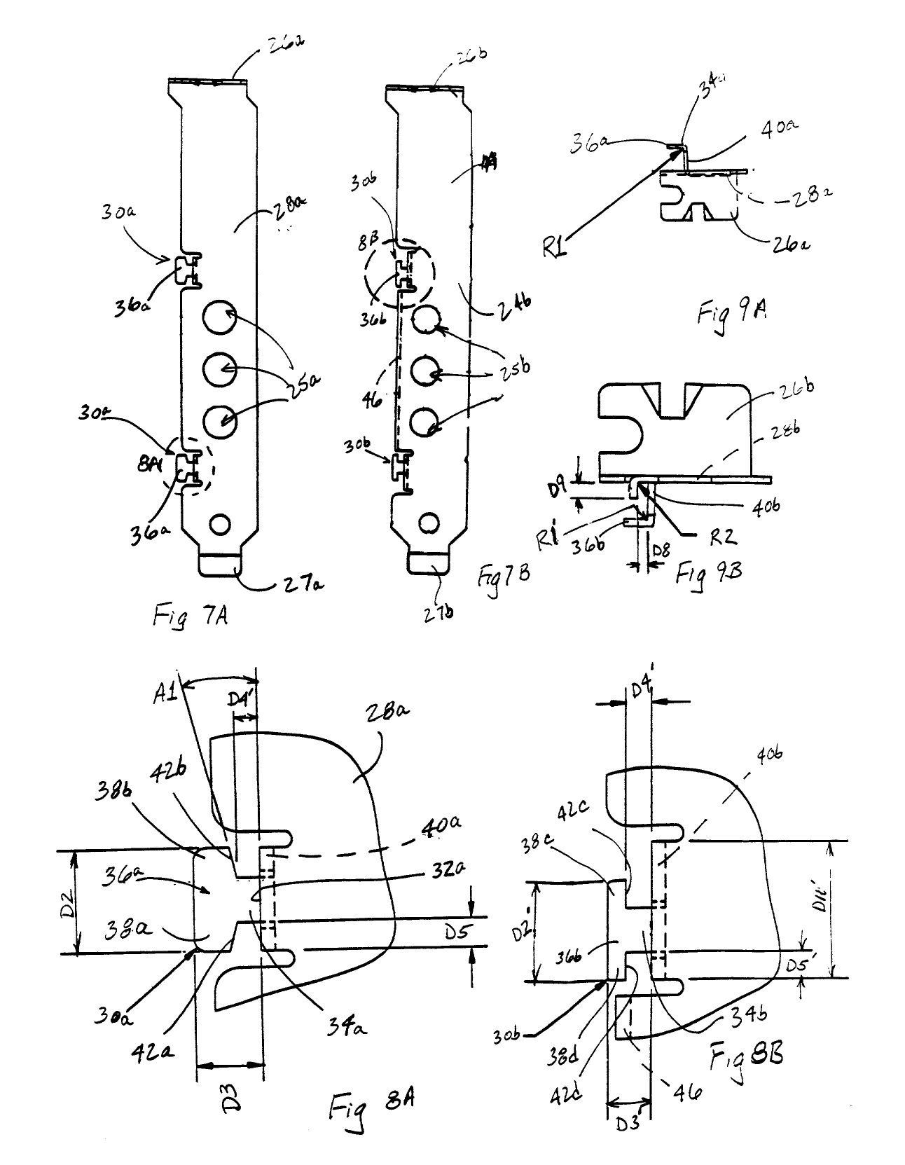

Tab 36a extends from web 34a, and includes a pair of wing-like ends 38a and 38b that extend laterally outwardly from web 34a. As best shown in FIG. 8A, oblique surfaces 42a and 42b are formed on the underside of tab ends 38a and 38b, respectively, so as to form ramps. Tab 36a (including ends 38a and 38b), in its unclamped state (shown, for example, in FIGS. 7A and 8A), defines a plane that is substantially co-planar with a plane defined by web 34a (that is, the portion of web 34a that is perpendicular to flange 40a). The plane of tab 36a is substantially perpendicular to a plane defined by flange 40a, and is substantially co-planar with a plane defined by bracket body 28a.

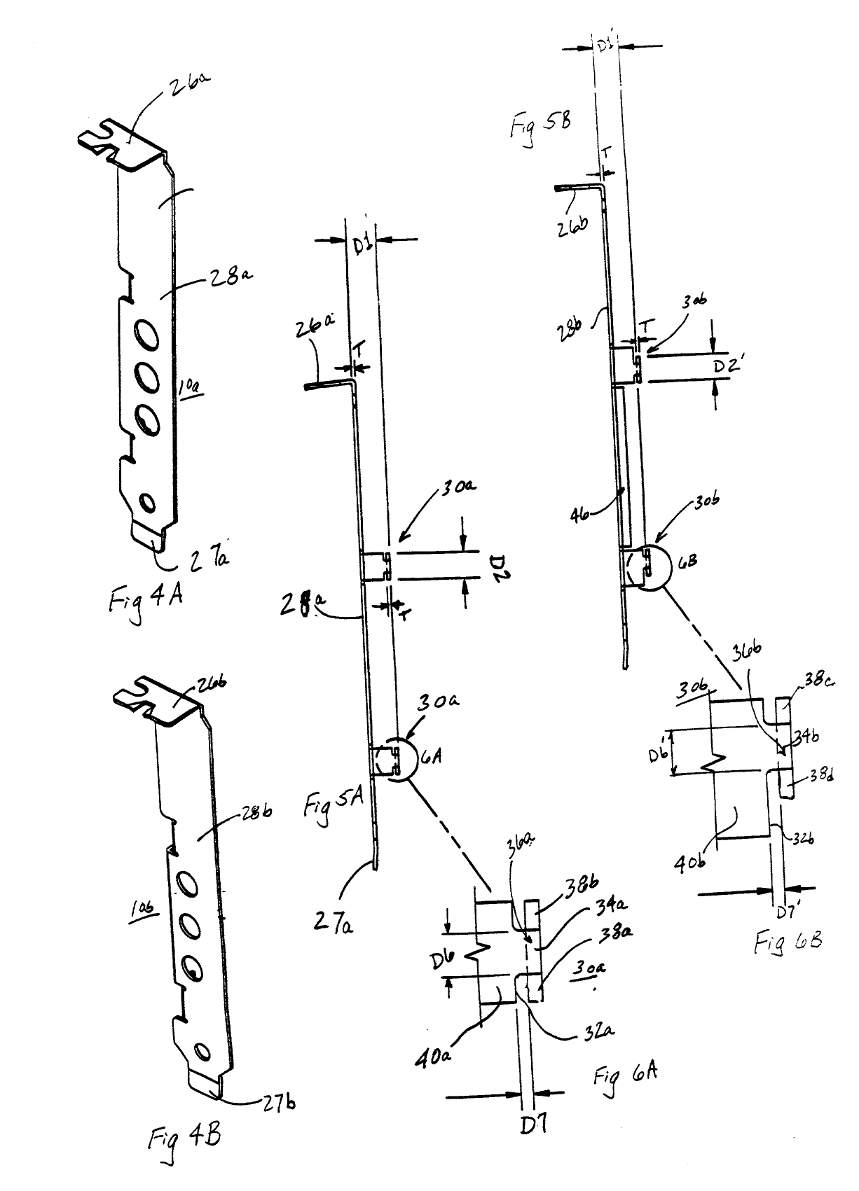

Exemplary dimensional information is provided herein to illustrate the first embodiment of the present invention. In this regard, the dimensional information does not limit the scope of the present invention, but rather is for illustrative purposes only, and additional embodiments will be clear to persons familiar with add-in card technology. As illustrated by dimension T in FIG. 5A, bracket 10 may be formed of 0.034 inches (0.88 m) thick CRS having a nickel plate finish, or other conventional material.

Flange 40a and tab 36a extend from body 28a such that the distance from the distal face of each undeformed tab 36a to the opposing side face of the bracket body (measured perpendicular to the plane of body 28a), as illustrated by dimension D1 in FIG. 5A, is 0.287+/−0.005 inches (7.29+/−0.13 mm). Thus, the distal face of each undeformed tab 36a extends outwardly from body 28a by approximately 0.253 inches (6.41 mm). As illustrated in FIG. 8A, each undeformed tab 36a preferably is 0.250 +/−0.005 inches (6.36+/−1.13 mm) wide, as illustrated by dimension D2, and is 0.161 inches (4.09 mm) high measured from base surface 32a (that is, extending outwardly from flange 40a) as illustrated by dimension D3.

The bottom of each oblique surface 42a and 42b begins 0.056+/−0.005 inches (1.42+/−0.13 mm) above base surface 32a, as illustrated by dimension D4. The angle formed between the oblique surface and a vertical reference line, as illustrated by angle A1 in FIG. 8A, preferably is between 5 and 40 degrees, more preferably between 10 and 20 degrees, and even more preferably approximately 15 degrees. The oblique angle for a particular use may be chosen according to conventional engineering principles, including the desired relationship between the amount of twisting and upward force created by the twisting.

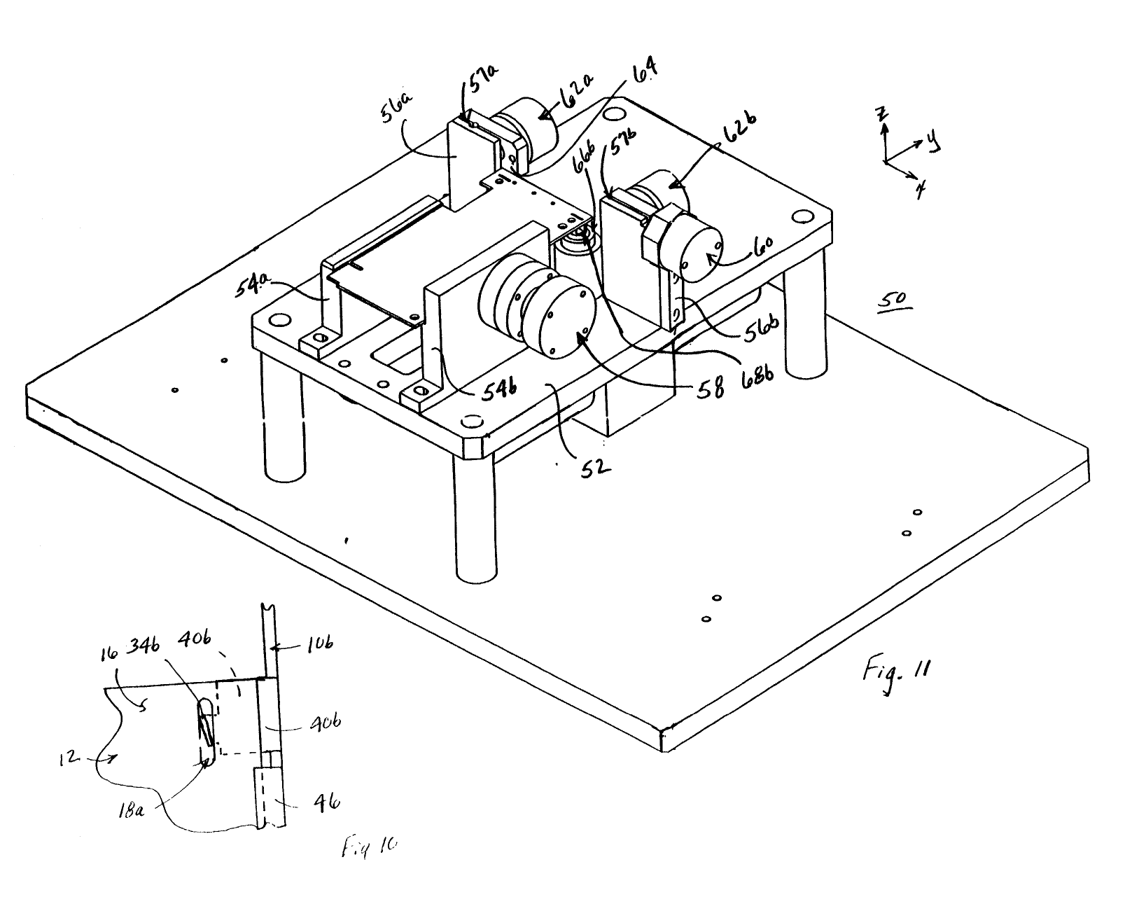

The web 34a is more narrow that the undeformed tab 36a by 0.070+/−0.005 inches (1.78 mm+/−0.13 mm) on each side thereof, as illustrated by dimension D5, such that web 34a is approximately 0.110 inches wide (that is, dimension D2 minus two times D5), as illustrated by dimension D6 in FIG. 6A. Flange 40a narrows to the width D6 to form the shoulder that is spaced apart from the proximal face of web 34a and tab 36a by 0.31 inches (0.79 mm), as illustrated by dimension D7. The bend of web 34a should have a small radius, such as a maximum radius of 0.005 inches (0.13 mm), as illustrated by radius R1 in FIG. 9A and explained below. Each slot 18a and 18b in PCB 12 is approximately 0.045 inches (1.43 mm) wide for receiving tab 36a. The exemplary PCB 12 is approximately 0.060 inches thick (that is, between sides 14 and 16).

In the assembled state of the card 9a, fastening members 30a clamp bracket 10a to PCB 12. Specifically, oblique surfaces 42a and 42b urge against first side 14 of PCB 12 opposite flanges 40a, thereby clamping PCB 12 between tabs 36a and flange 40a. Each of the webs 34a has a first side that contacts a first sidewall of the slot 18a, 18b and a second side that contacts an opposing second sidewall of the slot 18a, 18b (like the contact between webs 34b and slot 18a shown in FIG. 10 according to the second embodiment of the card 9b). The contact between the sides or corners of the webs 34a and the sidewalls of the slots 18a and 18b accurately positions PCB 12 relative to the face of bracket body 28a (that is, in a direction orthogonal to the face of bracket body 28a). Accurate positioning of PCB 12 relative to bracket 10a in a direction parallel to the longitudinal axis of bracket 10a may be achieved by alignment thereof prior to twisting of tabs 36a. Such accurate positioning may be by any means, and preferably is by the method described below according to another aspect of the present invention. Further, the contact between webs 34a and the sidewalls of slots 18a and 18b fastens the bracket 10a and the PCB 12 together in an interference fit.

According to the second embodiment of the present invention, bracket 10b (FIG. 1B) includes a fastening end 26b, an end tab 27b opposing fastening end 26b, a substantially planar body portion 28b therebetween, a pair of fastening members 30b, and an anti-rotation feature or member 46. Fastening end 26b includes conventional means for attaching bracket 10b to a chassis of a computer or other electronic device, such a recessed slot for receiving a self-tapping screw. A conventional screw hole through body 28b may be formed through body portion 28b near tab 27b.

FIGS. 1B and 5B through 9B show each fastening member 30b in its unclamped state (that is, prior to bracket 10b being affixed to PCB 12). Each fastening member 30b, shown in FIG. 6B for example, includes a base 32b, a web 34b, a tab 36b, and a flange 40b. As best shown in FIGS. 4B through 9B, flange 40b extends substantially perpendicularly from bracket body 28b. Web 34b extends from flange 40b and narrows therefrom (that is, flange 40b is wider than web 34b). Web 34b is bent at substantially a right angle from flange 40b such that a portion of web 34b is substantially perpendicular to flange 40b. Base 32b is formed on flange 40b and may include a portion of web 34b that is substantially parallel to flange 40b and a portion of web 34b that is formed at a right angle to flange 40b.

Tab 36b extends laterally from web 34b, and includes a pair of wing-like ends 38c and 38d. Ends 38c and 38c extend outwardly from web 34b. As shown for example in FIG. 8A, the underside of ends 38c and 38d substantially are flat and mutually parallel, and are substantially parallel to a plane defined by flange 40b (and/or to a plane defined by the PCB 12 upon assembly thereof). The underside of ends 38c and 48d are designated by reference numerals 42c and 42d, as shown in FIG. 8B. Tab 36b (including ends 38c and 38d), in its unclamped state (shown, for example, in FIGS. 7B and 8B), defines a plane that is substantially co-planar with a plane defined by web 34b (that is, the portion of web 34b that is perpendicular to flange 40b). The plane of tab 36b is substantially perpendicular to a plane defined by flange 40b, and is substantially co-planar with a plane defined by bracket body 28b. The parallel relationship between the tabs and the bracket body is beneficial because, among other reasons, the clamping force created by the webs contacting the PCB slots will be substantially perpendicular the bracket body. However, the present invention encompasses non-parallel relationships among the undeformed tabs, flanges, and bracket.

Exemplary dimensional information is provided herein to illustrate the second embodiment of the present invention. In this regard, the dimensional information does not limit the scope of the present invention, but rather is for illustrative purposes only, and additional embodiments will be clear to persons familiar with add-in card technology. As illustrated by dimension T′ in FIG. 5B, bracket 10b may be formed of 0.034 inches (0.88 m) thick CRS having a nickel plate finish, or like suitable material.

Flange 40b and tab 36b extend from body 28b such that the distance from the distal tip of each undeformed tab 36b to the opposing side face of the bracket body (as measured perpendicular to the plane of body 28b), as illustrated by dimension D1′ in FIG. 5B, is 0.253+/−0.005 inches (6.43+/−0.13 mm). Thus, each undeformed tab 36b extends outwardly from body 28b by approximately 0.219 inches (5.56 mm). As shown in FIGS. 5B through 8B, each undeformed tab 36b preferably is 0.250+/−0.005 inches (6.35+/−1.13 mm) wide, as illustrated by dimension D2′, and is 0.110+/−0.005 inches (2.79+/−0.13 mm) high measured from base surface 32b (that is, extending outwardly from the upper surface of flange 40b) as illustrated by dimension D3′. The underside surfaces 42c and 42d are 0.64+0.005/−0.000 inches (1.63+0.13/−0.00 mm) above base surface 32b, as illustrated by dimension D4′. As shown in FIGS. 7B and 8B, each tab 36b is offset from the centerline of flange 40b toward a transverse centerline of the center of bracket body 28b. Specifically, flange 40b is 0.343 inches (8.71 mm) wide, as indicated by dimension D10′ (FIG. 8B) and web 34b is offset by 0.070+/−0.005 inches (1.78 mm+/−0.13 mm) from an edge of flange 40b, as illustrated by dimension D10′. FIG. 10, from which tab 36b is removed for clarity, also shows the offset of web 34b relative to the centerline of flange 40b. The offset configuration provides flanges with sufficient strength while spacing the flanges from the holes in the bracket body that receive jacks 20.

Flange 40b narrows to the width D6′ to form the shoulder that is spaced apart from the proximal face of web 34b and tab 36b by 0.31 inches (0.79 mm), as illustrated by dimension D7′. The bend of web 34a should have a small radius, such as a maximum radius of 0.005 inches (0.13 mm), as illustrated by radius R1′ in FIG. 9B and explained below.

Anti-rotation member 46 extends from the body 28b at a substantially right angle thereto, and preferably is straight to as to form a flange that extends from body 28b. Member 46 extends longitudinally between fastening members 30b so as to span a significant portion of the height of PCB 12, and preferably more than half, and even more preferably more than about two-thirds of the height of PCB 12. Member 46 preferably is substantially parallel to flange 40b and is spaced apart therefrom to form a gap therebetween that is approximately 0.52+0.005/−0.000 inches (1.22+0.13/−0.00 mm), as indicated by dimension D8 in FIG. 9B. Member 46 extends outwardly from the face of bracket body 28b by approximately 0.078+/−0.005 inches (1.98+/−0.13 mm), as indicated by dimension D9 in FIG. 9B. Each slot 18a and 18b is approximately 0.045 inches (1.43 mm) wide for receiving tab 36b. The exemplary PCB is approximately 0.060 inches thick (that is, between sides 14 and 16).

In the assembled state of the card 9b, fastening members 30b clamp bracket 10b to PCB 12. Specifically, the underside surfaces 42c and 42d, which are best shown in FIG. 8B, urge against second side 16 of PCB 12 opposite flanges 40b, thereby clamping PCB 12 between tabs 36b and flanges 40b. As shown in FIG. 10, each of the webs 34b has a first side or corner that contacts a first sidewall of the slot 18a, 18b and a second side or corner that contacts an opposing second sidewall of the slot 18a, 18b. The contact between the sides or corners of the webs 34b and the sidewalls of the slots 18a and 18b accurately positions PCB 12 relative to the face of bracket body 28b (that is, in a direction orthogonal to the face of bracket body 28b). Accurate positioning of PCB 12 relative to bracket 10b in a direction parallel to the longitudinal axis of bracket 10b may be achieved by alignment thereof upon twisting of tabs 36b. Such accurate positioning may be by any means, and preferably is by the method described below according to another aspect of the present invention. Further, the contact between webs 34b and the sidewalls of slots 18a and 18b fastens the bracket and the PCB together in an interference fit.

In some circumstances and applications, the clamping action of tabs 36a or 36b cause PCB 12 to rotate or roll relative to bracket 10a or 10b, which causes the plane of the major portion of PCB 12 and the plane to body 28a or 28b of the bracket to deform from their perpendicular relationship. Assemblies employing tabs having oblique surfaces 42a and 42b may be especially prone to such rolling or rotation. Anti-rotation member 46 prevents or diminishes such rotation. Specifically, and as shown in FIGS. 1B and 10, a proximal edge of PCB 12 contacts an underside of anti-rotation member 46 and thereby restrains the proximal edge from rotating or rolling away from the face of flange 40b. Preferably, the dimension of the gap between the inner surfaces of anti-rotation member 46 and flanges 40b (which preferably are parallel) is approximately equal to or slightly less than the thickness of the PCB 12, as provided above by the thickness of PCB 12 and dimension D8.

Jacks 20 are inserted into the corresponding holes 25b in bracket 10b in a first direction and tabs 36b are inserted into PCB slots 18a and 18b in a second direction that is substantially perpendicular to the first direction. As explained more fully below, bracket 10b is rotated or rolled relative to PCB 12 to facilitate insertion of the jacks 20 and tabs into the holes and slots. Therefore, the dimension between the proximal edge of PCB 12 and the slots 18a and 18b should be chosen to enable such pivoting or rolling assembly. Further, the dimension that anti-rotation member 46 protrudes from bracket body 28b (that is, dimension D9) should be chosen to enable pivoting or rolling bracket 10b relative to PCB 12. In this regard, anti-rotation member 46 preferably is sufficiently short such that it contacts only an edge portion of PCB 12.

According to another aspect of the present invention and as shown in FIG. 11, an apparatus 50 for joining bracket 10a or 10b to the PCB 12 by positioning each component and actuating the fasteners 30a or 30b is provided. Apparatus 50 actuates fasteners 30a or 30b, and thereby joins bracket 10a or 10b and PCB 12 together, by deforming tabs 36a or 36b upon insertion of the tabs into PCB slots 18a and 18b. Apparatus 50 includes a base 52, a pair of PCB supports 54a and 54b, a pair of bracket supports 56a and 56b, a PCB positioning actuator 58, a first bracket positioning actuator 60, a pair of second bracket positioning actuators 62a and 62b, and a pair of deformation actuators 66a and 66b (actuator 66a is hidden from view in FIG. 11). Each of the positioning actuators preferably is a linear actuator (that is, has a linear stroke with an extended and unextended position), and each of the deformation actuators is a rotary actuator (that is, has a pivoted and unpivoted position about a pivot axis).

PCB supports 54a and 54b each are supported by base 52 and extend upwardly therefrom. Each support 54a and 54b has an inward shoulder formed thereon for receiving PCB 12. Supports 54a and 54b are mutually opposing and spaced apart approximately by the width of the PCB plus a clearance, thereby enabling PCB 12 to be inserted therebetween so as to rest on the support shoulders.

Bracket supports 56a and 56b each are supported by base 52 and extend upwardly therefrom. The operative portions of bracket supports 56a and 56b are disposed substantially perpendicular to PCB supports 54a and 54b. Bracket support 56a has a bracket slot 57a disposed therein for receiving bracket 10a or 10b at its end tab portion 27. Slot 57a may have an angled portion to enable insertion of end tab 27a or 27b therein. Alternatively, end tab 27a or 27b may protrude beyond slot 57a. Bracket support 56b has a bracket slot 57b, which is substantially aligned with slot 57a, for receiving the fastening end 26a or 26b of bracket 10a or 10b. Bracket slot 58b includes provisions, such as being formed in a right angle, to receive the bent end of fastening end 26a or 26b.

PCB positioning actuator 58 is disposed on a side of one of the PCB supports, such as support 54b, opposite the PCB 12. The moveable ram or push rod (not shown) of actuator 58 protrudes through support 54b to be enabled to contact the PCB resting on the support shoulders. Thus, while actuator 58 is in its extended position, PCB 12 is urged against the opposing support, thereby aligning the longitudinal axis of PCB 12 relative to apparatus 50. Preferably, the push rod is recessed within PCB support 54b or otherwise not in contact with the PCB while the push rod is in its unextended position.

First bracket positioning actuator 60 is disposed on bracket support 56b so as to be enabled to contact fastening end 26a or 26b of bracket 10a or 10b, and is disposed at an end of the bracket slot 56b such that its moveable ram or push rod moves parallel to the longitudinal axis of the bracket. Second bracket positioning actuators 62a and 62b are disposed on the side faces of bracket supports 56a and 56b, respectively, opposite PCB 12. Each of the actuators 62a and 62b includes a moveable ram or push rod that is capable of extending through its respective support into its respective slot 57a and 57b, respectively, in its extended position. Preferably, bracket 10a or 10b is easily insertable into the slots 57a and 57b while the bracket positioning actuators 60, 62a, and 62b are in their unextended positions.

Each deformation actuator 66a and 66b is disposed below the PCB and oriented such that its pivot axis is substantially vertical. Each deformation actuator 66a and 66b has a slot formed in the top portion thereof for receiving a tab 36a or 36b. Actuators 66a and 66b are disposed on base 52 such that the actuators 66a and 66b are parallel to and directly below PCB slots 18a and 18b, respectively, while PCB 12 is disposed in its final, clamped position.

The description of the operation of apparatus 50 will include, according to another aspect of the present invention, a description of a method of joining of bracket 10a or 10b and PCB 12, and a description of functional aspects of the fasteners 30a and 30b. In this regard, a PCB 12 and bracket 10a (for example) may be loosely assembled such that the tabs are inserted into slots 18a and 18b and jacks 20 are inserted into corresponding holes in the bracket body. Loosely assembling PCB 12 with bracket 10a requires rolling the bracket about its longitudinal axis (represented by the x-axis in FIG. 3) while the bracket moves in the z-direction such that the portion of bracket body 28a proximate the holes may clear jacks 20 while tabs 36a are inserted into slots 18a and 18b. Rolling PCB 12 and bracket 10b, in addition to the above techniques, includes positioning the proximal edge of PCB 12 under anti-rotation member 46. As described above, the relative location of slots 18a and 18b and jacks 20, and the dimensions of anti-rotation member 46 should be chosen to enable such loose assembly, which preferably is by hand. Because the PCB 12 preferably lies flat against the flanges 40a and 40b, the radius R1 should be sufficiently small (such as according to the dimensions provided above) such that the radius R1 does not interfere with the edge of the PCB.

Upon loosely assembling PCB 12 and bracket 10a or 10b together, the assembly may be placed onto apparatus 50 by placing PCB 12 onto PCB supports 54a and 54b while bracket 10a or 10b is inserted into bracket supports 56a and 56b. PCB 12 may be inserted onto the shoulders of PCB supports 54a and 54b without regard for manually positioning PCB 12. PCB 12 is disposed with side 16 facing upwardly such that jacks 20 (omitted from FIG. 11 for clarity) are on the top side of PCB 12. Bracket 10a or 10b (not shown in FIG. 11 for clarity) is inserted into slots 57a and 57b. Deformation actuators 66a and 66b are disposed directly below (in the z-direction) PCB slots 18a and 18b such that tabs 36a or 36b are inserted into a pair of slots 68a (not shown in FIG. 11) and 68b upon insertion of the bracket into the slots 57a and 57b.

Upon insertion of the components onto apparatus 50 with PCB 12, the operator may begin the sequence of actuations, which preferably is controlled by a programmable means that enables the timing sequence and force applied by the actuators to be controlled and varied. Positioning actuator 58 may extend to urge PCB 12 in a transverse direction (that is, in the negative x-direction as indicated in FIG. 11) against the shoulder of the opposing support 54a. Approximately simultaneously or shortly thereafter, first bracket positioning actuator 60 may extend to urge the bracket in the negative x-direction (as indicated in FIG. 11). After the bracket is locked in the x-direction, second bracket positioning actuators 62a and 62b may extend to position the bracket against an inboard side of the supports 56a and 56b.

With the PCB 12 and bracket 10a or 10b positioned according to the desired configuration, deformation actuators 66a and 66b pivot to deform tabs 36a or 36b such that the sides of the web 34a or 34b contact the sidewalls of the slots 18a and 18b, thereby clamping the PCB and bracket together. FIG. 10 (from which the tabs are removed for clarity) illustrates the deformed state. The angle through which fastening members 30a or 30b are deformed by actuators 66a and 66b may be predetermined according to conventional engineering parameters according to the particular characteristics of the application in light of the present disclosure.

The process described above automatically positions the bracket 10a or 10b relative to PCB 12 according to the tolerances described above. Specifically, positioning actuators 58 and 60 urge PCB 12 and bracket 10a or 10b against stops to align the parts in a direction transverse to the longitudinal axis of PCB 12 (that is, along the x axis in FIG. 11). Prior to actuation of deformation actuators 66a and 66b, positioning actuators 62a and 62b urge bracket 10a or 10b against a stop and PCB 12 is urged against a stop along the x axis but is not urged by an actuator along its longitudinal axis (that is, along the y axis). Upon actuation of deformation actuators 66a and 66b, PCB 12 is accurately positioned along the y axis by the deformation of webs 34a or 34b as they urge against the sidewalls of slots 18a and 18b. In this regard, the automatic alignment and assembly of bracket 10a or 10b to PCB 12 is complete.

The embodiments provided herein illustrate aspects of the present invention. However, the present invention is not limited to particular embodiments, but rather encompasses embodiments, features, and aspects that will be apparent to persons familiar with printed circuit board technology in light of the present disclosure. For example, the first embodiment of the sound card according to the present invention, including tabs having an oblique underside, may employ the anti-rotation feature described with respect to the second embodiment of the sound card according to the present invention. Further, the present invention encompasses fasteners that clamp substantially entirely by the interference or contact between the webs 34a or 34b and the PCB slots without any contact between the face of the PCB 12 and undersides 42a and 42b or 42c and 42d of the tabs. Similarly, the present invention encompasses fasteners that clamp entirely by the contact between the face of the PCB 12 and such undersides of the tabs. Further, dimensions of the features may be chosen according to the parameters of the particular application in which the present invention is to be employed, as will be understood by persons familiar with printed circuit board technology in light of the present disclosure. Thus, the present invention is not limited to employing only the particular configuration and actuators described with respect to the apparatus, but rather encompasses employing any configuration that positions and restrains the bracket relative to the PCB prior to twisting tabs.

We claim:

1. An add-in card for a computer, comprising:
a substantially planar printed circuit board having a first slot and second slot formed therethrough proximate an end thereof; and
a bracket having a body and a first and a second fastening member extending from the body, the first fastening member protruding through the first slot, the second fastening member protruding through the second slot, each one of the fastening members including:
a flange extending from the body;
a web extending from the flange;
a double-ended tab extending from the web opposite the flange, the tab having an underside surface that contacts the printed circuit board to fasten the printed circuit board between the tab and the flange.

2. The card of claim 1 wherein the each one of the tabs is deformed by twisting relative to its web, and each one of the webs is deformed by twisting relative to its flange, each one of the webs having a first side that urges against a first sidewall of the slot and an opposing second side that urges against a second sidewall of the slot, whereby the web contacting the slot positions the printed circuit board relative to the bracket.

3. The card of claim 2 wherein the bracket further includes an anti-rotation member extending outwardly from the body, the anti-rotation member contacting a side of the printed circuit board opposite the flange, thereby preventing rotation between the printed circuit board and the cover upon said deforming the tabs.

4. The card of claim 3 wherein the anti-rotation member is substantially parallel to each one of the flanges.

5. The card of claim 4 wherein each one of the tab underside surfaces is substantially parallel to the flanges.

6. The card of claim 2 wherein at least one end of each one of the tabs forms an oblique surface on an underside of the tab, the oblique surface urging the printed circuit board to clamp the printed circuit board between the oblique surface and the flange.

7. The card of claim 2 wherein the web and the tab form a planar surface before the bracket and printed circuit board are fastened together.

8. The card of claim 2 wherein the flange defines a flange plane that is substantially perpendicular to a body plane defined by the body.

9. The card of claim 8 wherein a lower portion of the web extends from the flange and is bent to substantially form a right angle therewith.

10. The card of claim 2 wherein the tab forms a tab plane that after deformation is oblique to a body plane defined by the body.

11. The card of claim 2 wherein the tab forms a tab plane that after deformation is substantially perpendicular to a body plane defined by the body.

12. The card of claim 2 wherein the tab forms a tab plane that prior to deformation is substantially perpendicular to the flange plane.

13. The card of claim 2 wherein the web is approximately 0.034 inches thick.

14. The card of claim 13 wherein the slot is approximately 0.45 inches wide.

15. The card of claim 6 wherein the oblique surface forms an angle of between 5 and 40 degrees.

16. The card of claim 15 wherein the oblique surface forms an angle of between 10 and 20 degrees.

17. The card of claim 16 wherein the oblique surface forms an angle of approximately 15 degrees.

18. A method of fastening a mounting bracket to a printed circuit board of a computer add-in card, comprising the steps of:
(a) inserting tabs that extend from the mounting bracket into slots formed in the printed circuit board; and
(b) twisting the tabs relative to the slots to urge an underside of each one of the tabs against a top surface of the printed circuit board, thereby clamping a bottom surface of the printed circuit board against a flange of the mounting bracket.

19. The method of claim 18 wherein the inserting step (a) includes rolling the mounting bracket relative to the printed circuit board so as to enable a female connector mounted on the printed circuit board to align with a corresponding port formed in the mounting bracket, whereby a centerline of the female connector is substantially perpendicular to a body of the mounting bracket.

20. The method of claim 18 further comprising the step of (c) positioning the mounting bracket in a slot formed in a support prior to the twisting step (b).

21. The method of claim 20 further comprising the step of (d) positioning the printed circuit board on a support prior to the twisting step (b).

22. The method of claim 21 wherein the positioning step (d) includes urging the printed circuit board in a direction that is substantially parallel to a longitudinal axis of the bracket against the support.

23. The method of claim 21 wherein the positioning step (c) includes urging an end portion of the bracket along a longitudinal axis of the bracket until the bracket is longitudinally clamped in the bracket slot.

24. The method of claim 23 wherein the positioning step (c) includes urging a body portion of the bracket in a direction substantially perpendicular to the longitudinal axis of the bracket until the bracket is transversely clamped in the bracket slot.

25. The method of claim 18 wherein the twisting step (b) includes actuating the pair of jaws to twist the tab relative to the slot.

26. An apparatus for positioning and fastening a printed circuit board and a bracket comprising:
a printed circuit board support;
a bracket support having a slot formed therein for receiving a bracket;
a printed circuit board actuator coupled to the printed circuit board support for urging the printed circuit board against a stop portion of the print circuit board support;
a first bracket positioning actuator coupled to the bracket support for urging the bracket in a direction parallel to a longitudinal axis of the bracket against a longitudinal stop portion of the bracket support;
a second bracket positioning actuator coupled to the bracket support for urging the bracket in a direction substantially parallel to a transverse axis of the bracket against a transverse stop potion of the bracket support; and
a pair of deformation actuators, each one of the deformation actuators having jaws for receiving a tab coupled to the bracket, each one of the deformation actuators capable of pivoting the jaws to twist the tabs while the bracket is restrained against the bracket support and while the printed circuit board is restrained against the printed circuit board support.

27. The apparatus of claim 26 wherein the printed circuit board support includes a pair of opposing shoulders, each one of the shoulders capable of supporting an opposing edge of the printed circuit board, the stop portion of the printed circuit board support being formed opposite the printed circuit board positioning actuator.

28. The apparatus of claim 27 wherein the shoulders are disposed approximately perpendicular to the bracket slot.
